(19) United States
(12) Patent Application Publication
(10) Pub. No.: US 2008/0019142 A1
(43) Pub. Date: Jan. 24, 2008

(54) Lamp assembly adapted to illuminate a backlit sign

(75) Inventors: Radu-Cornel Rapeanu, Mont-Royal (CA); Zhi Gang Xing, Pointe Claire (CA); Michel Lambert, Laval (CA)

Correspondence Address: HOFFMAN & BARON, LLP, 6900 JERICHO TURNPIKE, SYOSSET, NY, 11791, US

(73) Assignee: Thomas & Betts International, Inc.

(21) Appl. No.: 11/477,304

(22) Filed: Jun. 29, 2006

(51) Int. Cl. H01L 33/00

(52) U.S. Cl. 362/555; 40/570

(57) ABSTRACT

A lamp assembly and method for illuminating a backlit sign include at least one circuit board and light emitting diodes mounted on the circuit board. The light emitting diodes are oriented such that a majority of emitted light or a beam from the circuit board is directed to only a portion of the backlit sign. The light emitting diodes are positioned uniformly around a perimeter of the circuit board to ensure uniform illumination around the lamp assembly. The circuit boards are arranged parallel to each other and perpendicular to a longitudinal axis of the lamp assembly. The lamp assembly includes a plurality of resistors mounted on the circuit board such that heat dissipated by the resistors is uniformly distributed over the circuit board. The lamp assembly also includes a Bridge rectifier to provide a DC output voltage from AC or DC input voltages.

### BACKGROUND OF THE INVENTION

1. Field of the Invention

The present invention generally relates to lamps for illuminating signs. In particular, the present invention is directed to a low-power LED-based lamp assembly adapted to illuminate backlit signs in hazardous locations.

2. Description of the Prior Art

A conventional backlit EXIT sign 10 for hazardous locations is shown in FIG. 1 and is based on lighting fixtures specially designed to meet the Underwriters Laboratories (UL) and Canadian Standards Association (CSA) standards of security for use in applications where flammable gas, vapor, liquid, combustible dust, and/or other particles can be or are present during normal operation. Such a lighting fixture includes a thick metal body 16 made of die-cast aluminum and a robust glass globe or cover 12, which absorbs and diffuses a significant portion of the light emitted by the lamp 14.

The sign 10 includes a housing 13 that is a metal shroud with a prismatic shape, which shields the lighting fixture. Typically, the fixture body 16 is fixed with screws on the housing 13 and an EXIT legend 11 is mounted on the lateral face(s) of the globe 12.

Due to the large size of the housing 13 and the light absorbed by the glass globe 12, the equipment requires a relatively powerful incandescent or fluorescent lamp 14, which consumes typically 15-25 Watts, to meet the illumination and uniformity levels required for emergency lighting. This level of power consumption has become prohibitive in recent years with an increasing market awareness for energy-efficient equipment. Incandescent EXIT signs are still marketed in the United States, but cannot be listed under the U.S. Environmental Protection Agency (EPA) Energy Star Program. In Canada, incandescent EXIT signs have been completely banned since the enforcement of the CSA-C860 regulation in November 2004.

Therefore, it would be desirable to provide a low-power source of illumination for signs adapted to be used in hazardous locations.

### SUMMARY OF THE INVENTION

A lamp assembly adapted to illuminate a backlit sign formed in accordance with one form of the present invention, which incorporates some of the preferred features, includes at least one circuit board having a surface, and a plurality of light emitting diodes mounted on the circuit board. The light emitting diodes are preferably uniformly distributed around the perimeter of the circuit board such that illumination from the lamp assembly is independent of its position in the socket. The light emitting diodes are oriented with respect to the surface of the circuit board such that a majority of emitted light or the beam from the circuit board is directed to a portion of the backlit sign. The lamp assembly may include a plurality of circuit boards arranged substantially parallel to each other and substantially perpendicular to a longitudinal axis of the lamp assembly.

The lamp assembly may be adapted for use in a hazardous location, such as an EXIT sign. The lamp assembly may include a plurality of resistors mounted on the circuit board such that heat dissipated by the resistors is substantially uniformly distributed over the circuit board. The lamp assembly may also include a Bridge rectifier adapted to provide a DC output voltage from an AC input voltage or DC input voltage.

The light emitting diodes may be oriented at 0 degrees, 22 degrees, and/or 45 degrees with respect to the surface of the circuit board. The lamp assembly is adapted to operate from a 6-volt input voltage, 12-volt input voltage, 24-volt input voltage, or 120-volt input voltage, and may operate from an AC input voltage and/or a DC input voltage. Each of the plurality of light emitting diodes may be oriented at substantially the same angle with respect to the surface of the corresponding circuit board, and the lamp assembly requires less than 5 Watts of power.

A method of illuminating a backlit sign in accordance with one form of the present invention, which incorporates some of the preferred features, includes providing at least one circuit board comprising a surface, and mounting a plurality of light emitting diodes on the circuit board. The light emitting diodes are oriented with respect to the surface of the circuit board such that a majority of light emitted or the beam from the circuit board is directed to a portion of the backlit sign. The method may include arranging circuit boards substantially parallel to each other, and arranging circuit boards substantially perpendicular to the longitudinal axis of the lamp assembly. The method may also include adapting the lamp assembly for use in a hazardous location, and positioning a plurality of resistors on the at least one circuit board such that heat dissipated by the plurality of resistors is substantially uniformly distributed over the circuit board.

The method may include providing a DC output voltage from an AC input voltage and/or a DC input voltage, and adapting the lamp assembly to operate from a 6-volt input voltage, 12-volt input voltage, 24-volt input voltage, or 120-volt input voltage. The method may also include orienting the light emitting diodes at 0 degrees, 22 degrees, and/or 45 degrees with respect to the surface of the circuit board, and orienting the light emitting diodes at substantially the same angle with respect to the surface of the circuit board. The method includes adapting the lamp assembly to operate with less than 5 Watts of power.

These and other objects, features, and advantages of this invention will become apparent from the following detailed description of illustrative embodiments thereof, which is to be read in connection with the accompanying drawings.

### BRIEF DESCRIPTION OF THE DRAWINGS

FIG. 1 is a pictorial diagram of a conventional incandescent lamp assembly adapted to illuminate an industrial sign.

FIG. 2 is a pictorial diagram of a light emitting diode (LED)-based lamp assembly formed in accordance with the present invention.

FIG. 3 is a schematic diagram of a first embodiment of the LED lamp assembly formed in accordance with the present invention.

FIG. 4 is a schematic diagram of a second embodiment of the LED lamp assembly formed in accordance with the present invention.

FIG. 5 is a schematic diagram of a third embodiment of the LED lamp assembly formed in accordance with the present invention.

FIG. 6 is a schematic diagram of a fourth embodiment of the LED lamp assembly formed in accordance with the present invention.

FIG. 7 is a top view of circuit boards in the first embodiment of the LED lamp assembly shown in FIG. 3.

FIG. 8 is a top view of circuit boards in the second, third, and fourth embodiments of the lamp assembly shown in FIGS. 4-6.

FIGS. 9a, 9b, and 9c are side views of an LED mounted on the circuit boards of the first, second, third, and fourth embodiments of the lamp assembly shown in FIGS. 7 and 8.

FIG. 10a is an exploded view of the first, second, and third embodiments of the lamp assembly.

FIG. 10b is a side view of a socket for use in the first, second, and third embodiments of the lamp assembly.

FIG. 10c is a side assembled view of the first, second, and third embodiments of the LED lamp assembly.

FIG. 11a is an exploded view of the fourth embodiment of the LED lamp assembly.

FIG. 11b is a side view of a socket for use in the fourth embodiment of the LED lamp assembly.

FIG. 11c is a side assembled view of the fourth embodiment of the LED lamp assembly.

### DETAILED DESCRIPTION OF THE PREFERRED EMBODIMENTS

The present invention provides a low-power light emitting diode (LED)-based lamp assembly adapted to illuminate signs, such as EXIT signs, in industrial environments with an elevated risk of fire or explosion, commonly referred to as hazardous locations. Conventional backlit EXIT signs for hazardous locations use incandescent or fluorescent light sources having a power consumption of at least 14 Watts, which is normally required by the special construction of such lighting fixtures. These and other conventional lamp assemblies cannot meet all requirements for typical applications in such circumstances, which include:
a. consumption of less than 5 Watts of power;
b. operation with both AC and DC input voltages and low-voltage input power supplies (6V, 12V, or 24V); and
c. provision of sufficient illumination to illuminate the legend of the sign through the lens of an explosion-proof-rated lighting fixture.

The lamp assembly formed in accordance with the present invention achieves each of the above requirements. In addition, the lamp assembly includes the following features:
a. the LED components are uniquely oriented in space to optimize the illumination of the sign legend through the thick and light-absorbent lens; and
b. the components of an AC/DC ballast inside the lamp assembly are designed and positioned to optimize heat distribution and/or uniformly distribute heat, which reduces the temperature of the lamp below the temperature of incandescent lamps, making the lamp assembly of the present invention a safer device to use in hazardous locations.

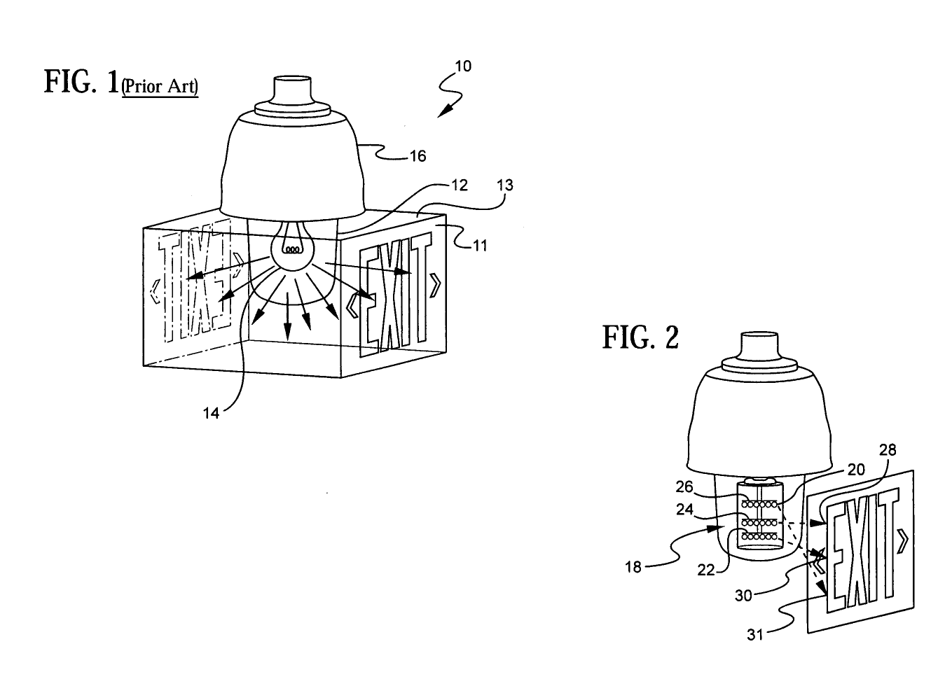

As shown in FIG. 2, the lamp assembly 18 preferably includes thirty-six (36) red LEDs 20. The LEDs 20 are preferably positioned on three substantially parallel planes or circuit boards 22, 24, 26, which are fixed horizontally on a central longitudinal axis of the lamp assembly 18. Each plane 22, 24, 26 is preferably a substantially circular printed circuit board (PCB) that provides a mounting surface for 12 LEDs 20 disposed radially around the perimeter of the PCB.

The LEDs 20 in each plane are each preferably oriented with a specific vertical angle, which is optimized to illuminate one third of the sign legend. The value of this angle and the distance of each PCB to the lamp socket are preferably calculated to aim the light beams as follows:
a. an upper PCB 26 has the LED beams aimed at a lower third 31 of the sign legend;
b. a middle PCB 24 has the LED beams aimed at an upper third 28 of the sign legend; and
c. a lower PCB 22 has the LED beams aimed at a centerline 30 of the sign legend.

The lamp assembly 18 preferably utilizes the following angles for the LEDs 20, which are measured from the surface of the corresponding PCB: 45° below the PCB surface for the top PCB 26, a horizontal aim for the center PCB 24, and 22° below the PCB surface for the middle PCB 22.

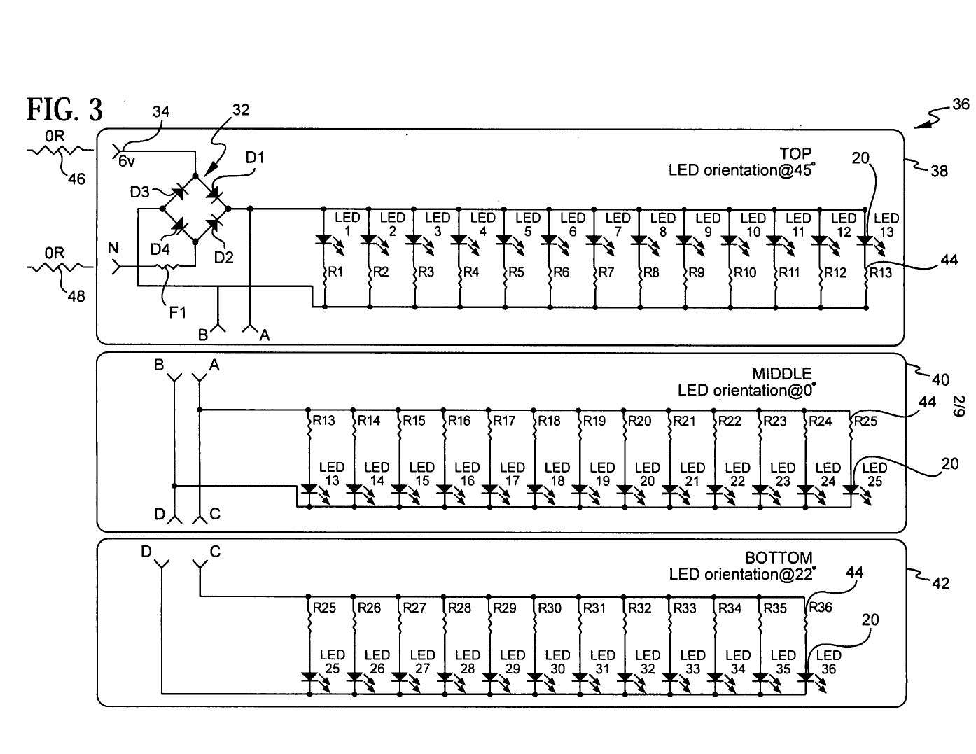

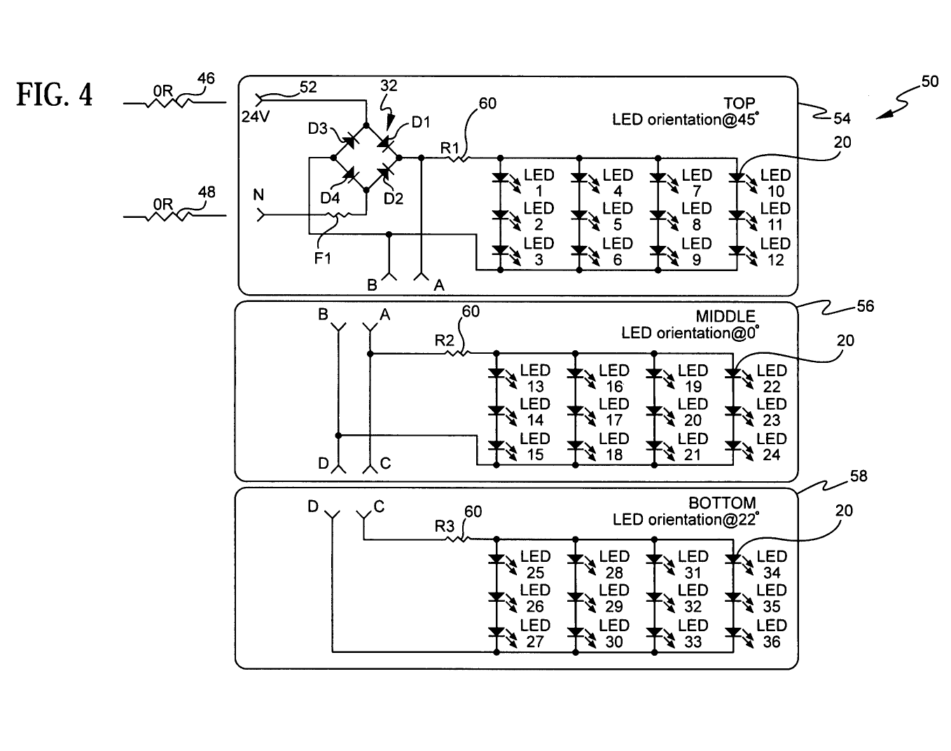

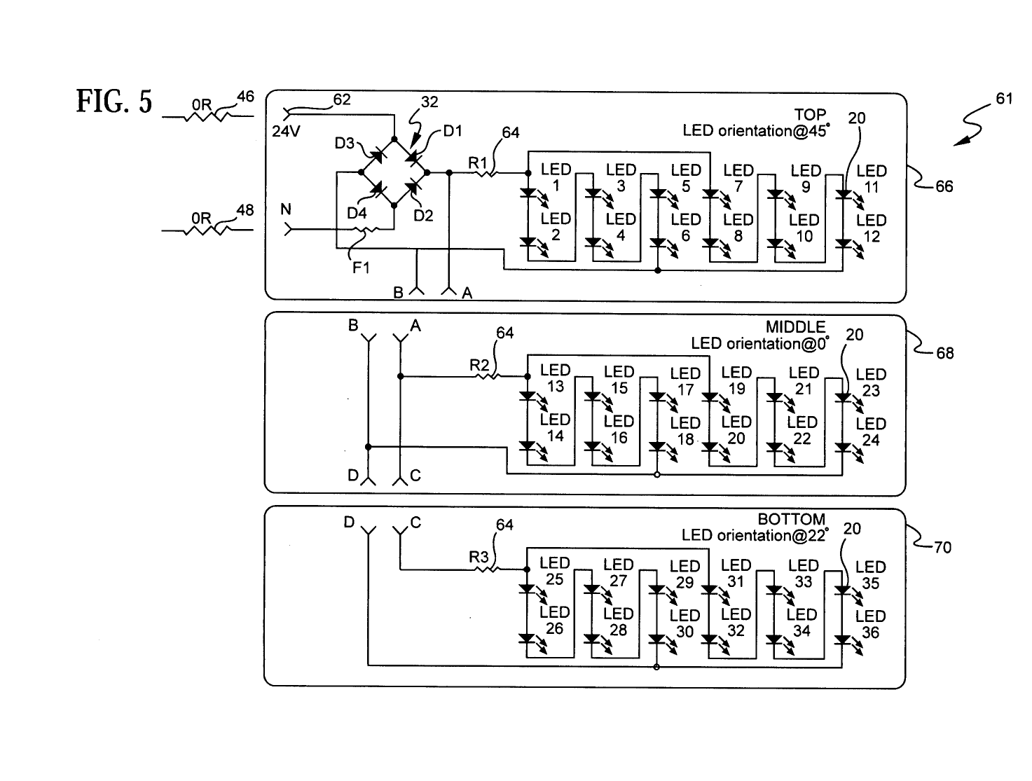

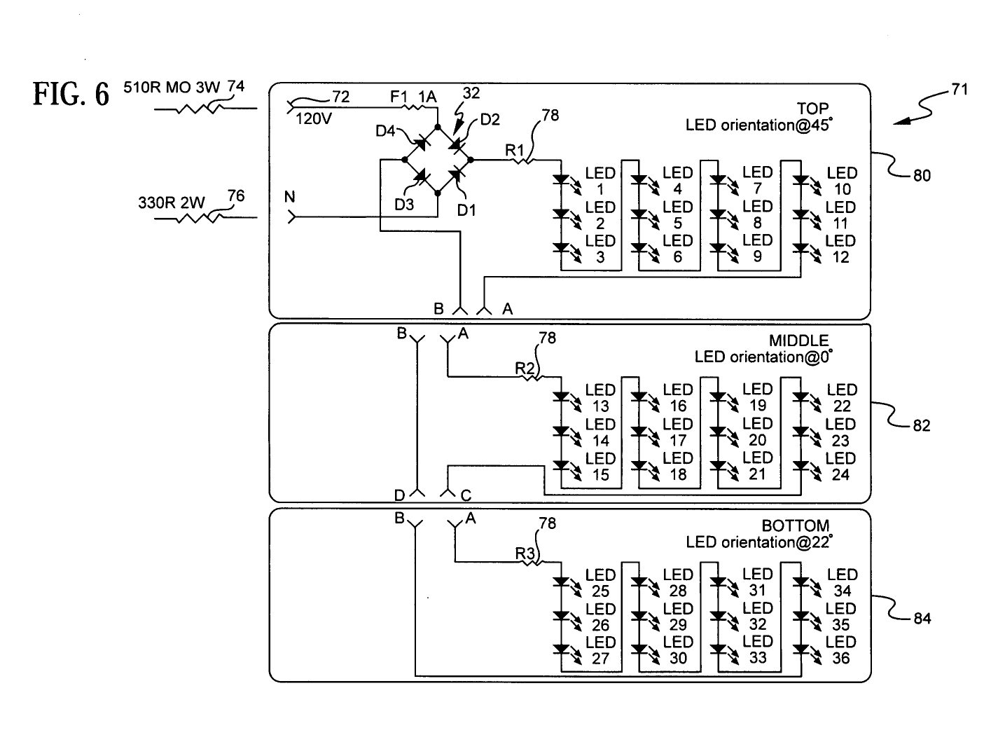

As shown in FIGS. 3-6, a rectifier bridge 32 and resistors are operatively coupled with the LEDs 20 to adapt an AC or DC input voltage to the constant-current requirements of the LEDs 20. Depending on the value of the input voltage, the quantity and value of the resistors connected in series with the LEDs 20 are preferably adapted to reduce electrical power dissipation per component and keep the temperature rise on each component within acceptable limits (such as 50-60° C.). Several acceptable input voltage values are preferably obtained by connecting the LEDs 20 on the PCB planes in series and/or parallel with resistor networks. FIGS. 3-6 are schematic diagrams of four embodiments that accept popular AC or DC input voltages used in emergency lighting: 6V (FIG. 3), 12V (FIG. 4), 24V (FIG. 5), and 120V (FIG. 6).

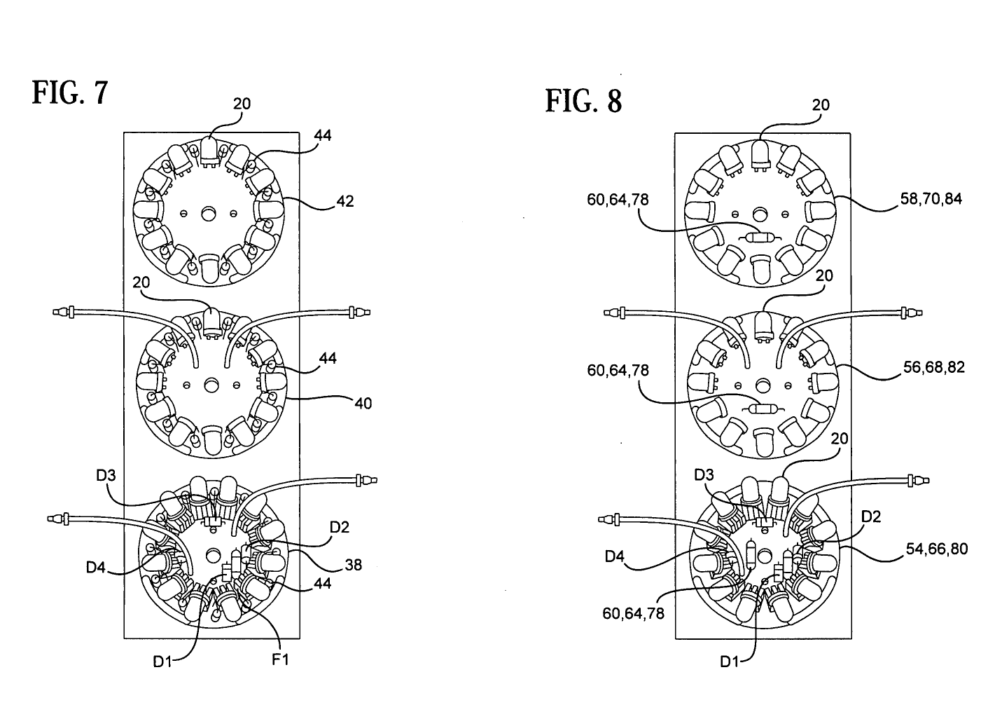

The lamp assembly 18 shown in FIG. 2 achieves the required levels of legend illumination with less than 5 Watts of power consumption, which is unattainable with incandescent or fluorescent lamps. This performance is made possible by optimizing the vertical aiming angle of the LEDs towards specific zones of the sign legend: top, center, and bottom. In the horizontal plane, the LEDs 20 preferably have a radial distribution (360°), which makes the illumination from the lamp assembly independent of the position of the lamp assembly in its socket and of the lighting fixture in the sign housing 13. That is, the LEDs on each of the circuit boards are preferably uniformly distributed around the perimeter of the circuit boards, as shown in FIGS. 7 and 8. Due to the uniform distribution of ballast resistors and/or distribution of the ballast resistors such that the heat dissipated therefrom is uniformly distributed on the printed circuit boards, the temperature rise inside the lamp assembly 18 (50-60° C.) is lower than the temperature of an incandescent bulb of 15-25 Watts. This advantageously makes the lamp assembly 18 safer to use in hazardous locations.

The circuits shown in FIGS. 3-6 function with both AC (in AC mode) and/or DC (battery or DC mode) input voltages. In AC mode, the current through the resistors and LEDs is preferably a full-wave rectified, unfiltered DC voltage.

Depending on the input voltage, the LEDs are installed in series and/or parallel to adapt their direct voltage, which is, for example, about 2.1 V, to the input voltage with minimum electrical losses on the remaining components, such as the resistors. The resistors are preferably used as ballasts to limit the current provided to the LEDs to an average value equal to the nominal current rating of the LED. In the preferred implementation, the average LED current is about 20 mA both in AC and DC modes.

The maximum operating temperature of components in the lamp assembly and consequently their heat dissipation is a primary concern. Since the lamp assembly is intended to be used in hazardous locations, the lower the temperature of its components, the lower the risk of self-ignition of gases and other substances present in the environment. The temperature rise on the LEDs is negligible since the total power consumption, which in the preferred embodiment is about 1.6 W, is uniformly distributed over thirty-six (36) LEDs. In contrast, the ballast resistors typically dissipate up to 3 Watts of power. For this reason, the resistors are preferably uniformly distributed on the circuit boards and in the lamp assembly.

For example, in a 6-volt embodiment shown in FIG. 3, the lamp assembly includes thirty-six (36) resistors on PCBs 38, 40, 42 and two (2) jumpers (zero Ohms) that are preferably mounted in the lamp socket. In the 12-volt and 24-volt embodiments shown in FIGS. 4 and 5, the lamp assembly preferably includes three (3) high-power resistors on the PCBs and jumpers in the lamp socket. In the 120-volt embodiment shown in FIG. 6, the lamp assembly preferably includes three (3) resistors on the PCBs and two (2) resistors in the lamp socket. With these combinations, the temperature rise on the components is preferably limited to below 60° C. (worst case) which is acceptable for EXIT sign applications in virtually all hazardous locations.

FIG. 3 is a schematic diagram of a first embodiment 36 of the lamp assembly formed in accordance with the present invention, which is adapted to accept a 6-volt AC and/or DC input voltage 34. The 6-volt input voltage 34 is supplied to input nodes of a bridge rectifier 32, which includes four (4) diodes D1-D4. The first embodiment 36 is preferably divided into three (3) printed circuit boards (PCBs) 38, 40, 42, each of which includes twelve (12) LEDs 20 in series with twelve (12) 150 ohm resistors 44. A fuse F1 is preferably connected in series between the 6-volt input voltage 34 and an input node of the bridge rectifier 32. Each of the LEDs 20 is connected in series with one of the resistors 44, and the series combinations of one LED 20 and one resistor 44 are connected in parallel with each other and the output terminals of the bridge rectifier 32. In the first embodiment 36 shown in FIG. 3, jumpers 46, 48 are used to connect the 6-volt input voltage 34 to input nodes of the bridge rectifier 32.

The LEDs 20 on a top circuit board 38 are preferably oriented at 45 degrees with respect to the surface of the circuit board. The LEDs 20 on the middle circuit board 40 are preferably oriented at 0 degrees or substantially parallel with the surface of the circuit board, and the LEDs 20 on the bottom circuit board 42 are preferably oriented at 22 degrees with respect to the surface of the circuit board. These orientations are preferably maintained in the first, second, third, and fourth embodiments shown in FIGS. 3-6.

FIG. 4 shows a second embodiment 50 of the lamp assembly, which is adapted to accept a 12-volt input voltage 52. The second embodiment is substantially similar to the first embodiment shown in FIG. 3, except for the quantity and connection of the resistors, and the connection of the LEDs. In the second embodiment, each of the circuit boards 54, 56, 58 preferably includes a 56 Ohm resistor 60 connected in series with an output node of the bridge rectifier 32 and the parallel network of four (4) groups of three (3) serially connected LEDs 20.

FIG. 5 shows a third embodiment 61, which is adapted to accept a 24-volt input voltage 62. The third embodiment 61 is substantially similar to the second embodiment 50 shown in FIG. 4, except for the value of the resistors and the connection of the LEDs 20. In the third embodiment, each of the circuit boards 66, 68, 70 preferably includes a 220 Ohm resistor 64 connected in series with an output node of the bridge rectifier 32 and the parallel network of two (2) groups of six (6) serially connected LEDs 20.

FIG. 6 shows a fourth embodiment 71, which is adapted to accept a 120-volt input voltage 72. The fourth embodiment 71 is substantially similar to the second embodiment 50 shown in FIG. 4, except for the value of the resistors and the connection of the LEDs 20. In the fourth embodiment, each of the circuit boards 80, 82, 84 preferably includes a 330 Ohm resistor 78 connected in series with an output node of the bridge rectifier 32 and the parallel network of twelve (12) serially connected LEDs 20.

FIG. 7 shows a top view of the bottom circuit board 38, middle circuit board 40, and top circuit board 42 of the first embodiment 38 of the lamp assembly shown in FIG. 3. The circuit boards 38, 40, 42 are preferably circular in shape with the resistors 44 and LEDs 20 mounted around the perimeter of the circuit boards 38, 40, 42. The LEDs 20 are preferably located uniformly around the perimeter of the circuit boards 38, 40, 42, such that illumination from the lamp assembly is substantially uniform around the lamp assembly, which makes illumination from the lamp assembly independent of the position of the lamp assembly in its socket or the lighting fixture in the shroud 16. In addition, the angular extent in the horizontal plane of the beam from any LED multiplied by the quantity of LEDs on the same plane or circuit board is preferably at least 360 degrees to ensure continuous illumination around the entire lamp assembly without dark spots. For example, if the angular extent of the beam from each LED on the circuit board is 12 degrees, then there must be at least thirty (30) LEDs (12 times 30 equals 360) evenly distributed around the perimeter of that circuit board to ensure that there are no dark spots. Even more preferably, in this example, there should be more than thirty (30) LEDs to ensure overlap between adjacent beams from the LEDs. The diodes D1-D4 of the bridge rectifier 32 are preferably mounted within a circle defined by the LEDs 20 on the top circuit board 42, as is the fuse F1.

Similarly, FIG. 8 shows a top view of the bottom circuit boards 58, 70, 84, middle circuit boards 56, 68, 82, and top circuit boards 54, 66, 80 for each of the second, third and fourth embodiments of the lamp assembly shown in FIGS. 4-6. Placement of the components on each of the circuit boards is substantially similar to that in the first embodiment shown in FIG. 7, except that resistors 60, 64, and 78 in the second, third and fourth embodiments are preferably mounted in a central area of each of the circuit boards shown in FIG. 8.

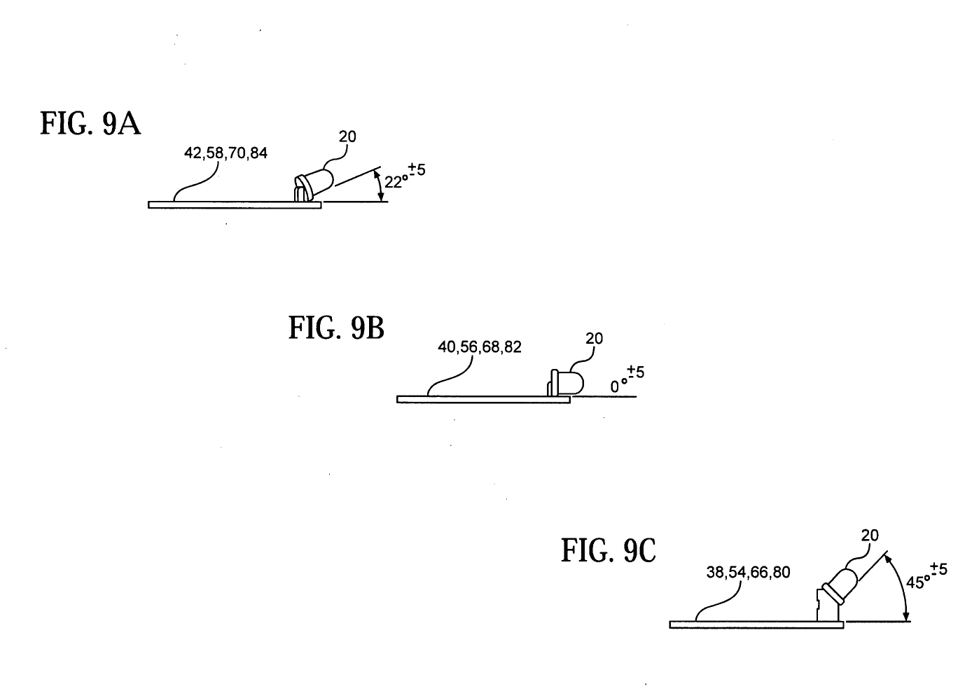

FIG. 9A shows a side view of the LED 20 and its orientation with respect to the surface of the bottom circuit boards 42, 58, 70, 84 in each of the embodiments of the lamp assembly. This orientation is preferably 22 degrees from the surface of the circuit board. Similarly, FIG. 9B shows the orientation of the LED 20 as being about 0 degrees from the surface of the middle circuit boards 40, 56, 68, 82 in each of the embodiments of the lamp assembly. Likewise, FIG. 9C shows the orientation of the LED 20 as being 45 degrees from the surface of the top circuit boards 38, 54, 66, 80 in each of the embodiments of the lamp assembly.

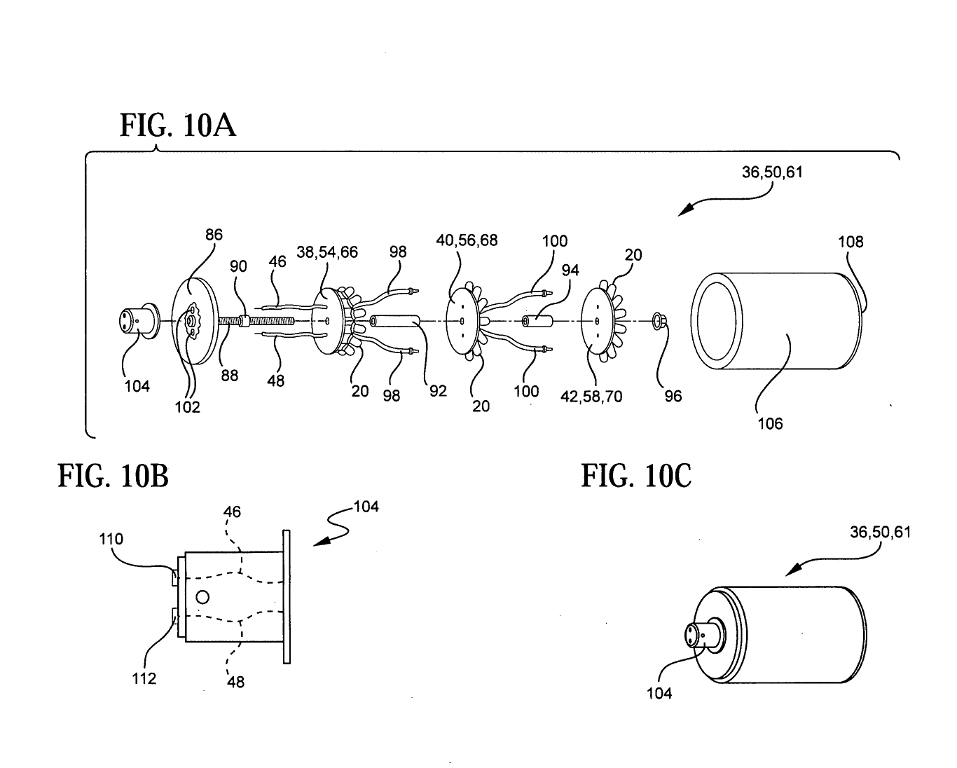

FIG. 10A shows an exploded side view of the first, second, and third embodiments of the lamp assembly 36, 50, 61. The lamp assemblies 36, 50, 61 preferably include a base disk 86, through which a screw 88 is inserted to maintain the vertical alignment of each of the top circuit board 38, 54, 66, middle circuit board 40, 56, 68, and bottom circuit board 42, 58, 70. The screw 88 also extends through apertures in each of the circuit boards, which are held in their vertical positions along the screw 88 by spacers 90, 92, 94 of various dimensions. A nut 96 is then applied to the end of the screw to retain each of the components thereon.

Wires 98 preferably connect the top circuit board 38, 54, 66 to the middle circuit board 40, 56, 68, and wires 100 connect the middle circuit board 40, 56, 68 to the bottom circuit board 42, 58, 70. Wires 46, 48 preferably extend through apertures 102 in the base disk 86 to connect the top circuit board 38, 54, 66 to a socket 104. A cover 106 is placed over the entire assembly and is pressed-fitted around the circumference of the base disk 86 and/or glued. The cover 106 is preferably manufactured from a transparent material, such as Lexan®. The cover 106 also preferably includes a cap disk 108 that covers an end of the cover 106 opposite that of the socket 104.

FIG. 10C shows a side perspective view of the assembled lamp assembly 36, 50, 61. FIG. 10D shows a side view of the socket 104 with wires 46, 48 extending therethrough to connect to contacts 110, 112.

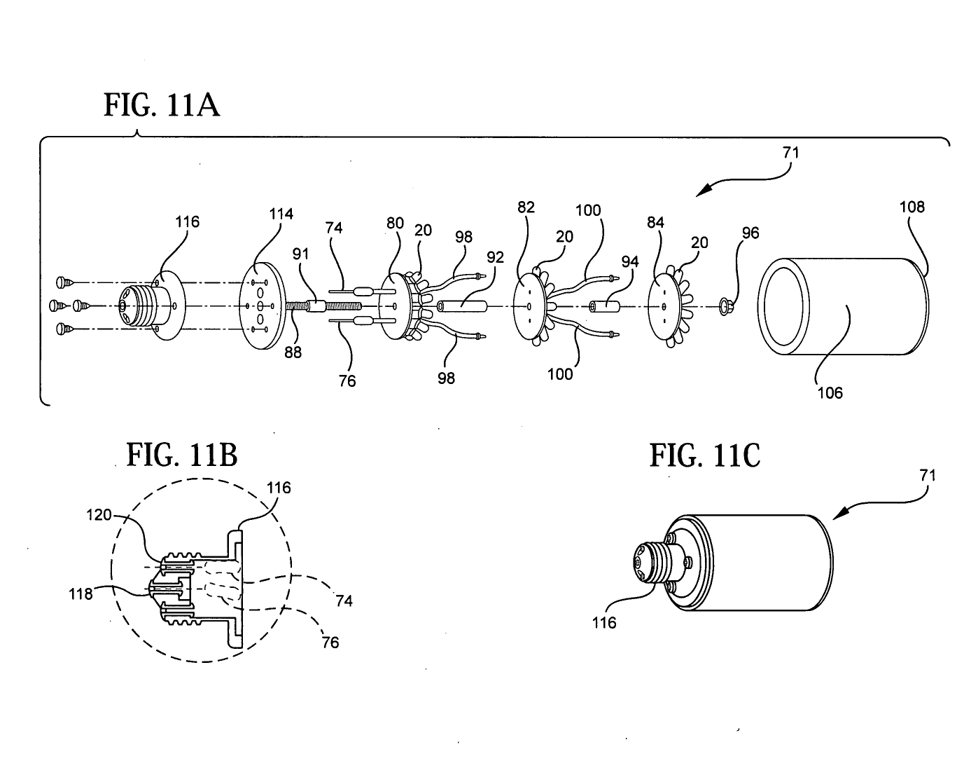

FIG. 11A shows an exploded side view of the fourth embodiment of the lamp assembly shown in FIG. 6, which is substantially similar to that shown in FIG. 10A, accept for the use of resistors 74, 76 to connect the top circuit board 80 to a socket 116, which is suitable for screwing in a standard lamp receptacle (medium base), and the configuration of holes in a base disk 114, which accepts screws that mount the socket 116 to the base disk 114. In addition, the size of a spacer 91 is preferably altered from the size of a corresponding spacer 92 shown in FIG. 10A to accommodate the increased length of resistors 74, 76 when compared with wires 46, 48.

An external view of the fourth embodiment office lamp assembly is shown in FIG. 1C, which is substantially similar to that shown in FIG. 1C, except for the socket 116. FIG. 1B shows a side cross-sectional view of the socket 116 having the resistors 74, 76 mounted therein and connected to a center contact 118 and a side contact 120.

The lamp assemblies described above are provided as examples of the preferred embodiments, but are not intended to limit the scope of the present invention in any manner. Various modifications to the preferred embodiments are intended to be within the scope of the present invention including the following:
a. use of the lamp assembly in signs with different sizes of legend, to accommodate various length of words (EXIT, SORTIE, SALIDA, and the like), directional indicators, pictograms, and the like.
b. a different total number of LEDs;
c. a different number of PCBs;
d. different aiming angles for the LEDs;
e. different input voltages; and
f. different colors of LEDs (such as green, blue, white, and the like).

Although illustrative embodiments of the present invention have been described herein with reference to the accompanying drawings, it is to be understood that the invention is not limited to those precise embodiments, and that various other changes and modifications may be affected therein by one skilled in the art without departing from the scope or spirit of the invention.

What is claimed is:

1. A lamp assembly adapted to illuminate a backlit sign comprising:
at least one circuit board comprising a surface; and
a plurality of light emitting diodes mounted on the at least one circuit board, the plurality of light emitting diodes being oriented with respect to the surface of the at least one circuit board such that a beam of light emitted from the at least one circuit board is directed to a portion of the backlit sign.

2. The lamp assembly adapted to illuminate a backlit sign defined by claim 1, further comprising a plurality of circuit boards arranged substantially parallel to each other.

3. The lamp assembly adapted to illuminate a backlit sign defined by claim 1, wherein the lamp assembly comprises a longitudinal axis, the lamp assembly further comprising a plurality of circuit boards arranged substantially perpendicular to the longitudinal axis of the lamp assembly.

4. The lamp assembly adapted to illuminate a backlit sign defined by claim 1, wherein the lamp assembly is adapted for use in a hazardous location.

5. The lamp assembly adapted to illuminate a backlit sign defined by claim 1, further comprising a plurality of resistors mounted on the at least one circuit board such that heat dissipated by the plurality of resistors is substantially uniformly distributed over the at least one circuit board.

6. The lamp assembly adapted to illuminate a backlit sign defined by claim 1, further comprising a Bridge rectifier adapted to provide a DC output voltage for the plurality of light emitting diodes from at least one of an AC input voltage and a DC input voltage.

7. The lamp assembly adapted to illuminate a backlit sign defined by claim 1, wherein the plurality of light emitting diodes is oriented at least one of 0 degrees, 22 degrees, and 45 degrees with respect to the surface of the at least one circuit board.

8. The lamp assembly adapted to illuminate a backlit sign defined by claim 1, wherein the lamp assembly is adapted to operate from at least one of a 6-volt input voltage, 12-volt input voltage, 24-volt input voltage, and 120-volt input voltage.

9. The lamp assembly adapted to illuminate a backlit sign defined by claim 1, wherein the lamp assembly is adapted to operate from at least one of an AC input voltage and a DC input voltage.

10. The lamp assembly adapted to illuminate a backlit sign defined by claim 1, further comprising a plurality of light emitting diodes, each of the plurality of light emitting diodes is oriented at substantially the same angle with respect to the surface of the at least one circuit board.

11. The lamp assembly adapted to illuminate a backlit sign defined by claim 1, wherein the lamp assembly requires less than 5 Watts of power.

12. The lamp assembly adapted to illuminate a backlit sign defined by claim 1, wherein the plurality of light emitting diodes are mounted uniformly around a perimeter of the at least one circuit board.

13. A lamp assembly adapted to illuminate a backlit sign comprising:
at least one circuit board comprising a surface;
a plurality of light emitting diodes mounted on the at least one circuit board; and
a plurality of resistors mounted on the at least one circuit board such that heat dissipated by the plurality of resistors is substantially uniformly distributed over the at least one circuit board.

14. A method of illuminating a backlit sign comprising:
providing at least one circuit board comprising a surface; and
mounting a plurality of light emitting diodes on the at least one circuit board, the plurality of light emitting diodes being oriented with respect to the surface of the at least one circuit board such that a beam of light emitted from the at least one circuit board is directed to a portion of the backlit sign.

15. The method of illuminating a backlit sign defined by claim 14, further comprising arranging a plurality of circuit boards substantially parallel to each other.

16. The method of illuminating a backlit sign defined by claim 14, wherein the lamp assembly comprises a longitudinal axis, further comprising arranging a plurality of circuit boards substantially perpendicular to the longitudinal axis of the lamp assembly.

17. The method of illuminating a backlit sign defined by claim 14, further comprising adapting the lamp assembly for use in a hazardous location.

18. The method of illuminating a backlit sign defined by claim 14, further comprising positioning a plurality of resistors on the at least one circuit board such that heat dissipated by the plurality of resistors is substantially uniformly distributed over the at least one circuit board.

19. The method of illuminating a backlit sign defined by claim 14, further comprising providing a DC output voltage for the plurality of light emitting diodes from at least one of an AC input voltage and a DC input voltage.

20. The method of illuminating a backlit sign defined by claim 14, further comprising orienting the at least one light emitting diode at least one of 0 degrees, 22 degrees, and 45 degrees with respect to the surface of the at least one circuit board.

21. The method of illuminating a backlit sign defined by claim 14, further comprising adapting the lamp assembly to operate from at least one of a 6-volt input voltage, 12-volt input voltage, 24-volt input voltage, and 120-volt input voltage.

22. The method of illuminating a backlit sign defined by claim 14, further comprising adapting the lamp assembly to operate from at least one of an AC input voltage and a DC input voltage.

23. The method of illuminating a backlit sign defined by claim 14, further comprising orienting the plurality of light emitting diodes at substantially the same angle with respect to the surface of the at least one circuit board.

24. The method of illuminating a backlit sign defined by claim 14, further comprising adapting the lamp assembly to operate with less than 5 Watts of power.

25. The method of illuminating a backlit sign defined by claim 14, further comprising mounting the plurality of light emitting diodes uniformly around a perimeter of the at least one circuit board.

26. A method of illuminating a backlit sign comprising:
providing at least one circuit board comprising a surface;
mounting a plurality of light emitting diodes on the at least one circuit board; and
mounting a plurality of resistors on the at least one circuit board such that heat dissipated by the plurality of resistors is substantially uniformly distributed on the at least one circuit board.
